(19) United States
(12) Patent Application Publication
(10) Pub. No.: US 2025/0164879 A1
(43) Pub. Date: May 22, 2025

(54) PHOTORESIST-FREE OPTICAL PATTERNING METHOD FOR COLLOIDAL NANOCRYSTALS IN GREEN SOLVENT

(71) Applicant: NANJING UNIVERSITY, Nanjing (CN)

(72) Inventors: Yuanyuan WANG, Nanjing (CN); Pengwei XIAO, Nanjing (CN); Zhoufan ZHANG, Nanjing (CN); Huanhuan LUO, Nanjing (CN)

(73) Assignee: NANJING UNIVERSITY, Nanjing (CN)

(21) Appl. No.: 18/841,401

(22) PCT Filed: Mar. 1, 2023
(86) PCT No.: PCT/CN2023/078990

§ 371 Date: Aug. 26, 2024

(30) Foreign Application Priority Data
Aug. 31, 2022 (CN) 202211052499.1

(51) Int. Cl. G03F 7/029; G03F 7/32

(52) U.S. Cl. CPC G03F 7/029; G03F 7/32

(57) ABSTRACT

A photoresist-free optical patterning method for colloidal nanocrystals in a green solvent is provided. A photosensitive ligand structurally similar to the green solvent is introduced to successfully disperse nanocrystals in the green solvent and complete direct photolithography on the nanocrystals. Photosensitive nanocrystals obtained through ligand exchange can be effectively dispersed in the green solvent to absorb spectra emitted by the green solvent, thereby preserving about 90% of photoluminescence quantum yield (PLQY) while keeping the morphology and size unchanged. The present invention solves the problem that nanocrystals cannot be subject to direct photolithography in the green solvent, and is expected to be applied to the commercialization of nanocrystals in the field of electroluminescent and photoluminescent quantum dot displays.

### CROSS REFERENCE TO THE RELATED APPLICATIONS

This application is the national phase entry of International Application No. PCT/CN2023/078990, filed on Mar. 1, 2023, which is based upon and claims priority to Chinese Patent Application No. 202211052499.1, filed on Aug. 31, 2022, the entire contents of which are incorporated herein by reference.

### TECHNICAL FIELD

The present invention belongs to the technical field of nanomaterials and optical etching, and particularly relates to a photoresist-free optical patterning method for colloidal nanocrystals in a green solvent.

### BACKGROUND

At present, optical patterning methods for nanocrystals (NCs) are mainly based on two means: (1) Photoresist-based photolithography. This means mainly utilizes mature commercial photoresists, including two different ways: (i) Firstly, direct photolithography is performed on a commercial photoresist and a portion of the photoresist is peeled off using a developer, then a photoresist template is filled with nanocrystals, and finally the photoresist is peeled off to obtain patterned nanocrystals (FIG. 1A). (ii) Nanocrystals are directly mixed with a commercial photoresist, then direct photolithography is performed on the mixture, the nanocrystals are embedded into the photoresist, and a portion of the photoresist and the nanocrystals are peeled off in a developer (FIG. 1B). (2) Photoresist-free direct photolithography. A photo-acid generator (PAG) or a bifunctional surface ligand is introduced into a colloidal nanocrystal system (as shown in FIG. 2). The introduced photosensitive material decomposes at a specific wavelength to change the surface environment of nanocrystals and then affect the stability of the nanocrystals in some solvents, and a corresponding solvent is selected to wash the nanocrystals and remove the unexposed portion (FIG. 1C). Such ligands have a wide photosensitive range from deep ultraviolet (DUV, 254 nm) to visible light (450 nm), and can be used for photolithography of nanocrystals containing specific photosensitive groups.

Nanocrystal patterning using a photoresist inevitably introduces the photoresists. However, the commercial photoresist cannot be effectively removed in the process of development, and the remaining photoresist will produce a great impact on the charge transfer and heat transfer properties of nanocrystals. Meanwhile, the cost of the photoresist is high, which will increase the cost of the nanocrystal patterning process.

In the photoresist-free photolithography, although the problems caused by the introduction of commercial photoresists are avoided, nanocrystals cannot be directly dispersed in green solvents such as propylene glycol methyl ether acetate (PGMEA), diethylene glycol mono-ether acetate (DGMEA), and octane. The patterning process can only be performed in industrially unacceptable solvents such as toluene and N,N-dimethylformamide (DMF), which greatly limits the application of the current nanocrystal patterning process in actual industrial production. In addition, the introduction of functional ligands changes the composition of the surface of nanocrystals, and damages the surface of the nanocrystals to further affect the optical properties of the nanocrystals. Therefore, after patterning, the nanocrystals need to be post-treated to repair their surface, so as to restore some of their properties.

### SUMMARY

To solve the above technical problems in existing technologies, the present invention provides a photo induced crosslink lithography (PICL) and designs a type of bifunctional ligands. On the one hand, these ligands have some structures similar to those of green solvents. After being connected to the surface of nanocrystals by carboxylate or amino or mercapto groups, the ligands assist in dispersing nanocrystals in green solvents such as PGMEA, DGMEA, and octane according to the principle of “like dissolves like”. On the other hand, these ligands all have photosensitive methacryloyl or benzophenone groups, and due to the photosensitive properties of the groups, coupling polymerization can be performed under specific wavelengths of light, thereby achieving direct photolithography patterning of nanocrystals. This method retains the advantage of easy operation of the photoresist-free photolithography, does not damage the surface of nanocrystals, and can also retain the fluorescence property of nanocrystals and shorten the distance between nanocrystals while patterning is completed, thereby effectively improving the efficiency of charge transfer between nanocrystals.

The technical solution of the present invention is as follows:

A green photosensitive nanocrystal coating includes nanocrystals and a photosensitive ligand; the selected photosensitive ligand contains a group coordinated with the nanocrystals, such as a carboxylate or amino or mercapto group, and a methacryloyl or benzophenone photosensitive group.

Preferably, the photosensitive ligand is any one of ethyl 2-(3-mercaptopropionyloxy) methacrylate, 5-[3-methoxy-4-(2-methylprop-2-enoyloxy)phenyl]pent-4-enoic acid, (2E)-3-(3-methoxy-4-{2-[(2-methylprop-2-enoyl)oxy]ethoxy}phenyl)prop-2-enoic acid, 4-(4-(methacryloxy)phenoxy)-4-oxobutyric acid, mono-2-(methacryloxy)ethyl succinate, (E)-6-(4-(methacryloxy)phenyl)-4-oxyhex-5-enoic acid, (E)-6-(4-(methacryloxy)-3-methoxyphenyl)-4-oxohex-5-enoic acid, (E)-6-(4-(methacryloxy)-3,5-dimethoxyphenyl)-4-oxohex-5-enoic acid, 2-(6-(2-(methacryloxy)ethoxy)-2-oxo-2H-chromen-3-yl) acetic acid, phenyl-[4-(10-mercaptodecyloxy)phenyl]ketone, phenyl-[4-(10-mercaptodecylthio)phenyl]ketone, and 4-pyrrolidinyl-phenyl-[4-(10-mercaptodecylthio)phenyl]ketone.

Preferably, the nanocrystals contain a primitive organic ligand, and the primitive organic ligand is any one or a combination of carboxylic acid, phosphonic acid, and amine with fatty chains greater than 8 carbons. More preferably, the primitive organic ligand is any one or a combination of oleic acid, stearic acid, palmitic acid, oleamine, octadecylamine, and octadecylphosphonic acid.

Preferably, the nanocrystals include, but are not limited to, inorganic nanocrystals such as CdS, CdSe, CdSe/ZnS, CdSeS/ZnS, CdSe/CdZnSeS/ZnS, CdZnS/ZnS, CdZnSe/ZnS, ZnSe/ZnS, CdSe/CdS, CdSeS/CdS, InP, InP/ZnS, InP/ZnSe/ZnS, InGaP/ZnSe/ZnS, CdTe, PbS, PbSe, PbS/CdS, Fe₂O₃, Fe₃O₄, TiO₂, ITO, In₂O₃, CsPbBr₃, and MAPbBr₃.

The green photosensitive nanocrystal coating is prepared by the following method: performing ligand exchange on nanocrystals with an organic ligand on their surface and a photosensitive ligand. Specifically, a photosensitive ligand is added to a nanocrystal solution with an organic ligand on the surface to obtain a mixture, and the mixture is vigorously stirred or shaken to obtain a precipitate, namely, a product.

Preferably, the nanocrystal solution with the organic ligand on the surface is mixed with the photosensitive ligand in a mass ratio of 10:1, and the obtained mixture is vigorously stirred or shaken until the precipitate, namely, the product is generated. Preferably, the concentration of the photosensitive ligand is greater than or equal to 50 mg/mL.

Preferably, the ligand exchange is completed in an inert atmosphere.

A preparation method for a green photosensitive nanocrystal ink includes: dispersing the green photosensitive nanocrystal coating in a green solvent, where the green solvent is propylene glycol methyl ether acetate (PGMEA), ethylene glycol methyl ether acetate (EGMEA), diethylene glycol mono-ether acetate (DGMEA), propylene glycol methyl ether (PGME), or octane.

Preferably, the green photosensitive nanocrystal coating is dispersed in the green solvent to form a stable colloidal solution, and the concentration of the green photosensitive nanocrystal coating is 10-25 mg/mL.

A photoresist-free optical patterning method for colloidal nanocrystals in a green solvent includes the following steps: using the green photosensitive nanocrystal ink to prepare a continuous, dense, and thickness-controllable nanocrystal thin film on a substrate; pressing a mask engraved with a specific pattern onto the thin film, exposing in an ultraviolet light source, and developing in a developer.

Preferably, the substrate is a silicon wafer, a quartz plate, or a glass sheet.

Preferably, the developer is propylene glycol methyl ether acetate (PGMEA), ethylene glycol methyl ether acetate (EGMEA), diethylene glycol mono-ether acetate (DGMEA), propylene glycol methyl ether (PGME), or octane.

Compared with the prior art, the advantages of the present invention are as follows:

A photosensitive ligand structurally similar to the green solvent is introduced to successfully disperse nanocrystals in the green solvent, thus ensuring that the nanocrystals could be directly photolithographed.

Photosensitive nanocrystals obtained through ligand exchange can be effectively dispersed in the green solvent to absorb spectra emitted by the green solvent, thereby preserving about 90% of photoluminescence quantum yield (PLQY) while keeping the morphology and size unchanged. By exploring the mechanism, it is clear that the process is due to free radical polymerization of acrylyl in the photosensitive ligand structure under ultraviolet light conditions, thereby shortening the distance between nanocrystals and significantly reducing the solubility of nanocrystals in a solvent such as toluene or propylene glycol methyl ether acetate.

The present invention solves the problem that nanocrystals cannot be subject to direct photolithography in the green solvent. The process is expected to be applied to the commercialization of nanocrystals in the field of electroluminescent and photoluminescent quantum dot displays.

### BRIEF DESCRIPTION OF THE DRAWINGS

FIGS. 1A-1D are schematic illustrations of several methods for optical patterning of nanocrystals;

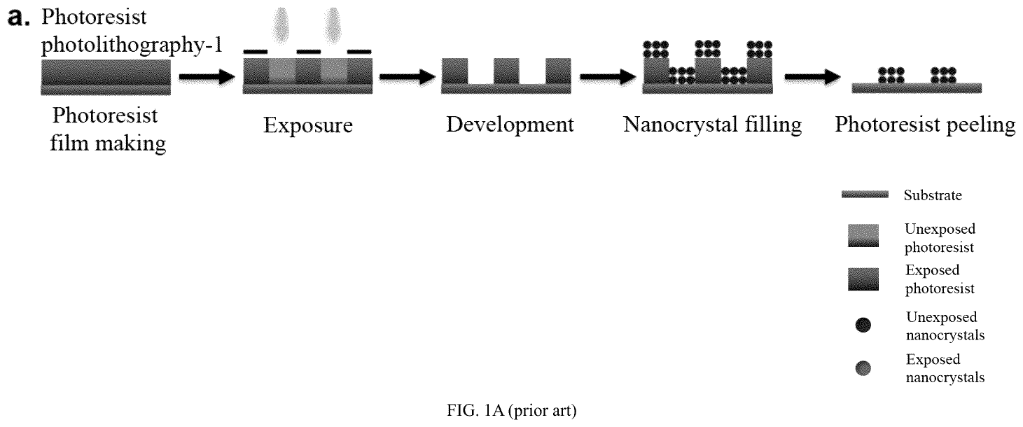

FIG. 1A illustrates photoresist-based optical etching technology 1; FIG. 1B illustrates photoresist-based optical etching technology 2; FIG. 1C illustrates photoresist-free photolithography; FIG. 1D illustrates an optical patterning method of the present invention, which does not have damage to fluorescence property;

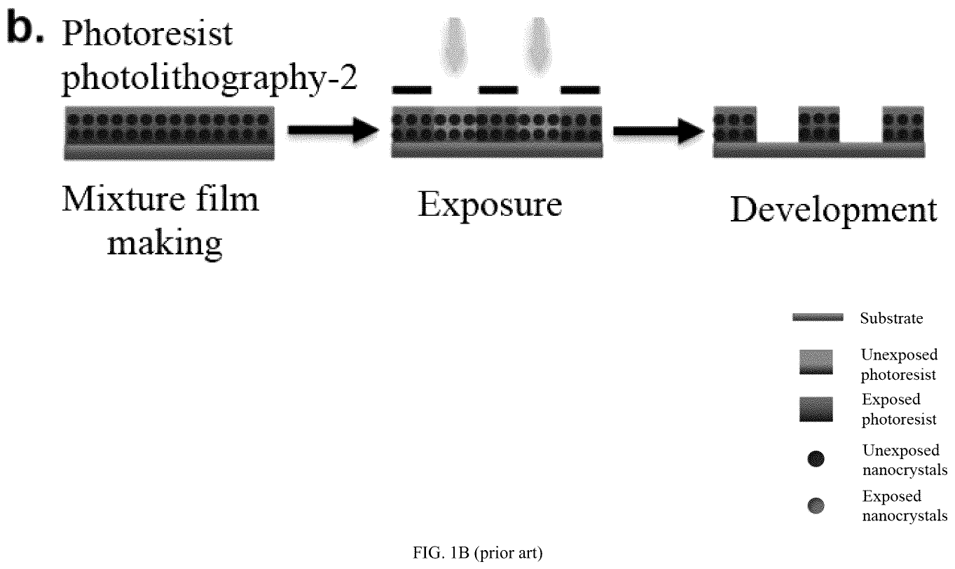

FIG. 2 illustrates introduction of a photo-acid generator (PAG) or a bifunctional surface ligand into a colloidal nanocrystal system to implement photoresist-free photolithography.

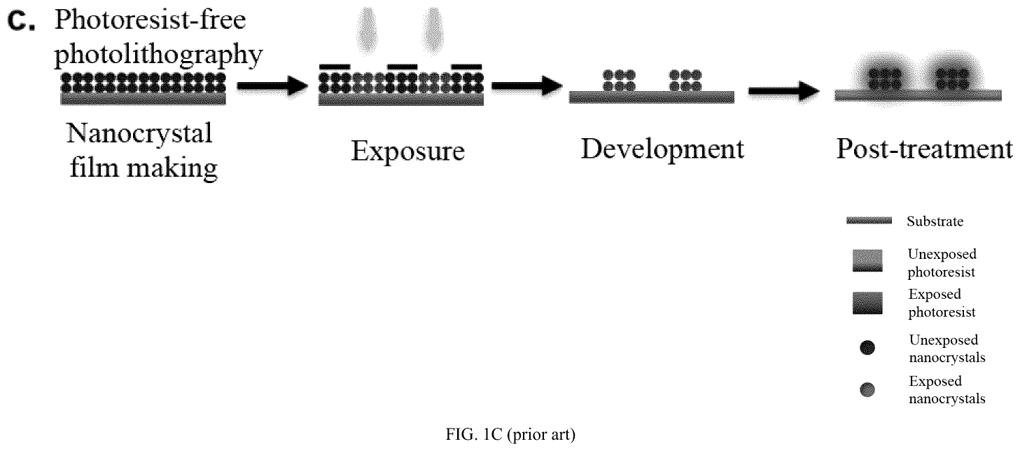

FIG. 3 is a schematic diagram of a method of surface treatment for nanocrystals in the present invention.

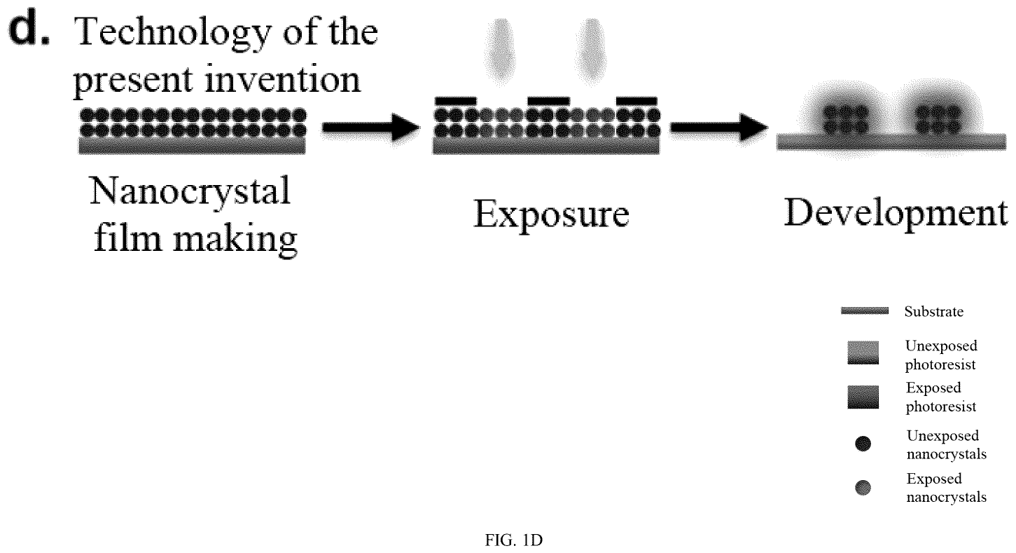

FIG. 4 is a schematic diagram of a photolithography process of the present invention.

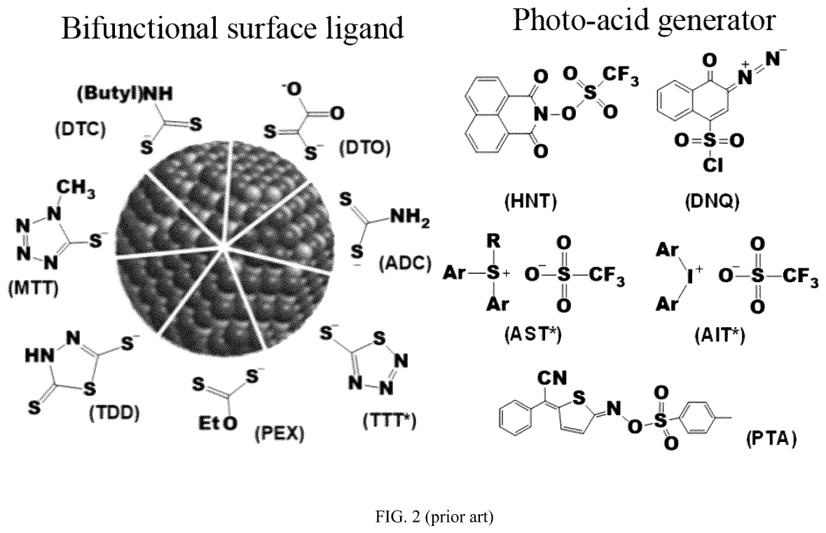

FIGS. 5A-5B illustrate a comparison of transmission electron microscopy images of nanocrystals before (FIG. 5A) and after (FIG. 5B) ligand exchange.

FIG. 6 illustrates a comparison of luminescent properties of nanocrystals before (black line) and after (gray line) photosensitive ligand treatment.

FIG. 7 illustrates a photolithography pattern of 2-(3-mercaptopropionyloxy)ethyl methacrylate as a ligand.

FIG. 8 illustrates a photolithography pattern of 5-[3-methoxy-4-(2-methylprop-2-enoyloxy)phenyl]pent-4-enoic acid as a ligand.

FIG. 9 illustrates a photolithography pattern of 2-(6-(2-(methacryloxy)ethoxy)-2-oxo-2H-chromen-3-yl)acetic acid as a ligand.

### DETAILED DESCRIPTION OF THE EMBODIMENTS

### Example 1

Direct photolithography of nanocrystals (quantum dots) in a green solvent using deep ultraviolet light as a light source and ethyl 2-(3-mercaptopropionyloxy) methacrylate as a ligand

All ligand exchanges were completed using an anhydrous solvent in a glove box filled with nitrogen gas (O₂ and H₂O less than 0.01 ppm). The photosensitive ligand used was ethyl 2-(3-mercaptopropionyloxy) methacrylate.

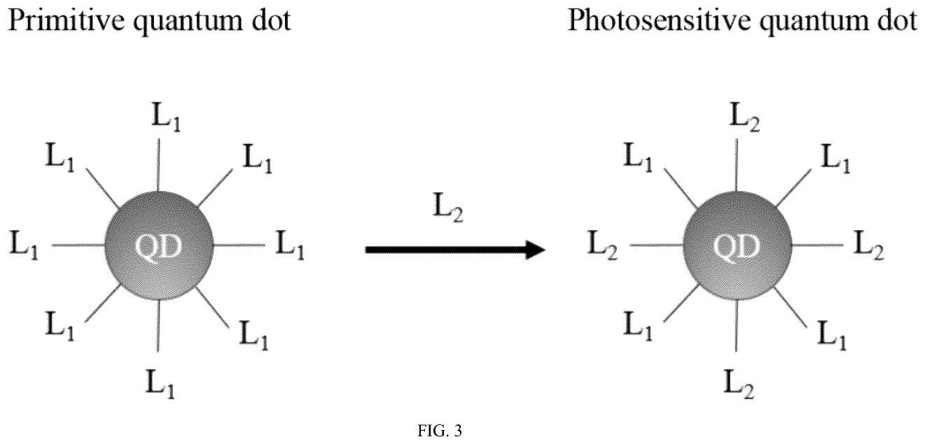

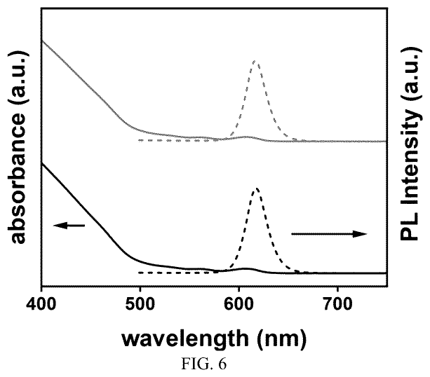

Red fluorescent nanocrystal CdSe/ZnS quantum dots with oleic acid on the surface were dispersed in n-hexane, and the ethyl 2-(3-mercaptopropionyloxy) methacrylate was a pure substance. Ligand exchange treatment was first performed using 200 μL of NCs solution (25 mg/mL), to which 20 μL of ethyl 2-(3-mercaptopropionyloxy) methacrylate was added. The obtained mixture was vigorously stirred or shaken until NCs precipitate was observed. After centrifugation, the precipitate was re-dispersed in 200 μL of PGMEA and excess ethyl 2-(3-mercaptopropionyloxy) methacrylate ligand was removed by precipitation with 1 mL of n-hexane. After centrifugation, the precipitate was dispersed in PGMEA to form a stable colloidal solution (10-25 mg/mL). The transmission electron microscopy (TEM) image of the material was shown in FIGS. 5A-5B. 10 μL of PGMEA solution of NCs was dropped onto the surface of a silicon wafer and spin-coated on a spin coater into a uniform thin film. A mask engraved with a specific pattern was pressed onto the thin film, exposed in a 254 nm ultraviolet light source, and developed in a PGMEA developer. The obtained pattern was shown in FIG. 7.

### Example 2

Direct photolithography of nanocrystals (quantum dots) in a green solvent using 365 nm as a light source and 5-[3-methoxy-4-(2-methylprop-2-enoyloxy)phenyl]pent-4-enoic acid as a ligand

All ligand exchanges were completed using an anhydrous solvent in a glove box filled with nitrogen gas (O₂ and H₂O less than 0.01 ppm). The photosensitive ligand used was 5-[3-methoxy-4-(2-methylprop-2-enoyloxy)phenyl]pent-4-enoic acid.

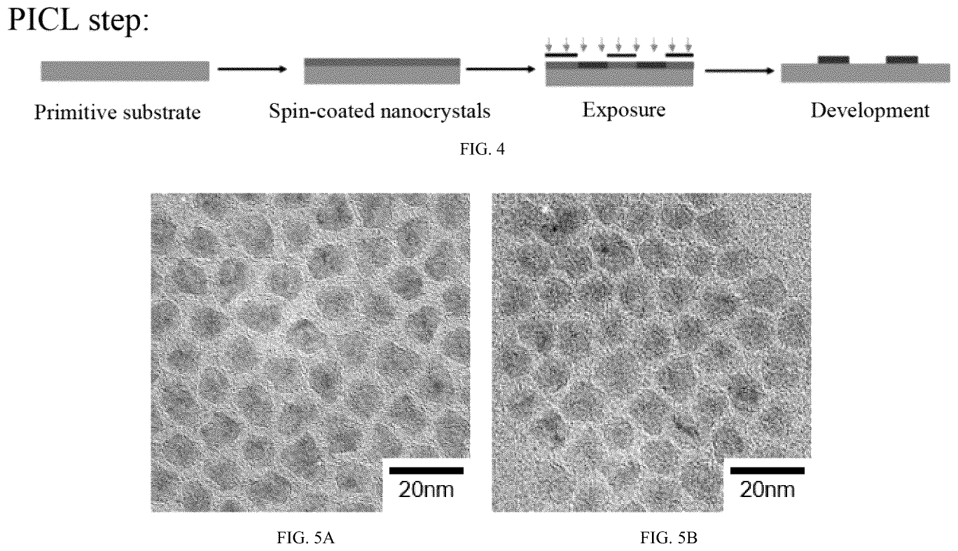

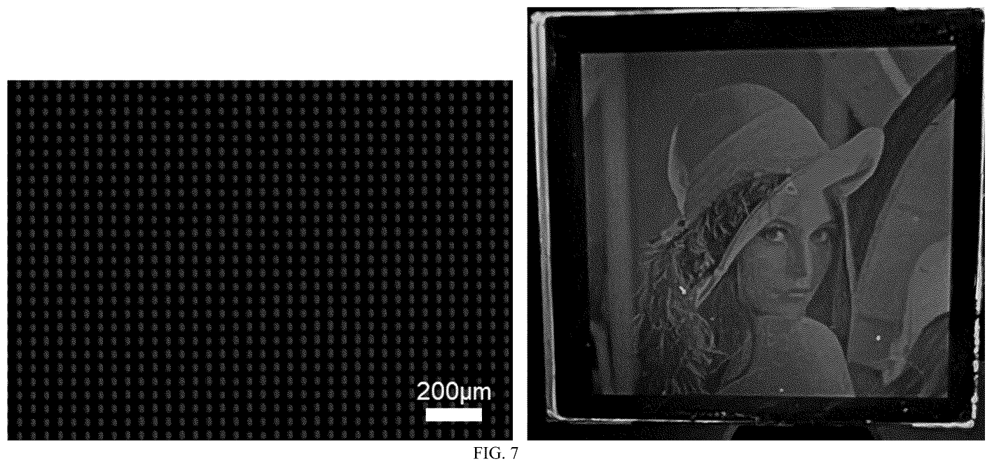

Green fluorescent nanocrystal CdSe/CdZnSeS quantum dots with oleic acid as a surface ligand were in n-hexane, dispersed and the 5-[3-methoxy-4-(2-methylprop-2-enoyloxy)phenyl]pent-4-enoic acid was prepared as a solution in the n-hexane. Ligand exchange treatment was first performed using 200 μL of NCs solution (25 mg/mL), to which 20 μL of n-hexane solution of 5-[3-methoxy-4-(2-methylprop-2-enoyloxy)phenyl]pent-4-enoic acid (50 mg/mL) was added. The obtained mixture was vigorously stirred or shaken until NCs precipitate was observed. After centrifugation, the precipitate was re-dispersed in 200 μL of PGMEA and excess 5-[3-methoxy-4-(2-methylprop-2-enoyloxy)phenyl]pent-4-enoic acid ligand was removed by precipitation with 1 mL of n-hexane. After centrifugation, the precipitate was dispersed in PGMEA to form a stable colloidal solution (10-25 mg/mL). The comparison of absorption and fluorescence spectra before and after treatment was shown in FIG. 6. 10 μL of PGMEA solution of NCs was dropped onto the surface of a silicon wafer and spin-coated on a spin coater into a uniform thin film. A mask engraved with a specific pattern was pressed onto the thin film, exposed in a 365 nm ultraviolet light source, and developed in a PGMEA developer. The obtained pattern was shown in FIG. 8. To fully demonstrate the universality of this method, photolithography was performed on CdSeS/ZnS quantum dots emitting red fluorescence and CdZnS/ZnS quantum dots emitting blue fluorescence to obtain nanocrystal patterns that retained fluorescence.

### Example 3

Direct photolithography of nanocrystals (quantum dots) in a green solvent using 405 nm as a light source and 2-(6-(2-(methacryloxy)ethoxy)-2-oxo-2H-chromen-3-yl)acetic acid as a ligand.

All ligand exchanges were completed using an anhydrous solvent in a glove box filled with nitrogen gas (O₂ and H₂O less than 0.01 ppm). The photosensitive ligand used was 2-(6-(2-(methacryloxy)ethoxy)-2-oxo-2H-chromen-3-yl)acetic acid.

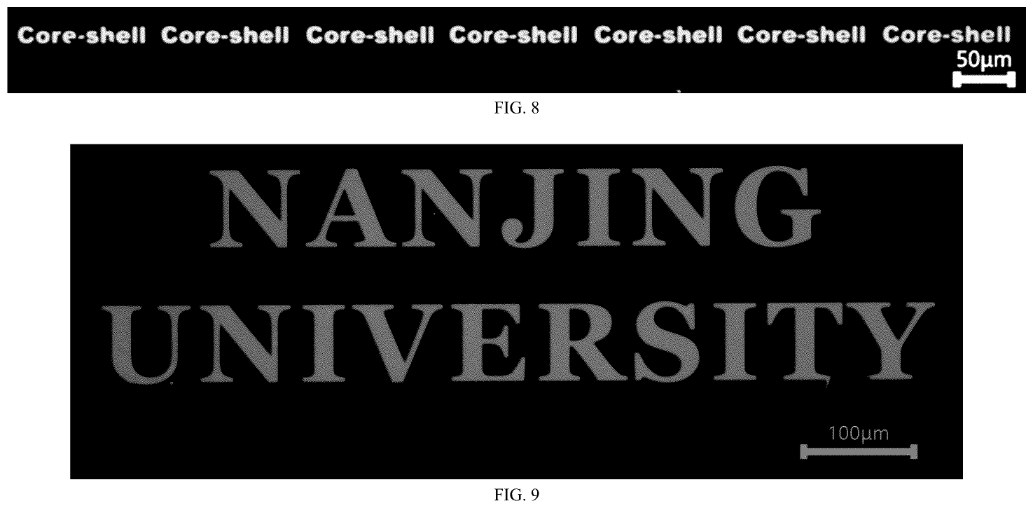

Green fluorescent nanocrystal CdSe/CdZnSeS quantum dots with oleic acid on the surface were dispersed in n-hexane, and the 2-(6-(2-(methacryloxy)ethoxy)-2-oxo-2H-chromen-3-yl)acetic acid was prepared as a solution in the n-hexane. Ligand exchange treatment was first performed using 200 μL of NCs solution (25 mg/mL), to which 20 μL of n-hexane solution of 2-(6-(2-(methacryloxy)ethoxy)-2-oxo-2H-chromen-3-yl)acetic acid (50 mg/mL) was added. The obtained mixture was vigorously stirred or shaken until NCs precipitate was observed. After centrifugation, the precipitate was re-dispersed in 200 μL of PGMEA and excess 2-(6-(2-(methacryloxy)ethoxy)-2-oxo-2H-chromen-3-yl)acetic acid ligand was removed by precipitation with 1 mL of n-hexane. After centrifugation, the precipitate was dispersed in PGMEA to form a stable colloidal solution (10-25 mg/mL). 10 μL of PGMEA solution of NCs was dropped onto the surface of a silicon wafer and spin-coated on a spin coater into a uniform thin film. A mask engraved with a specific pattern was pressed onto the thin film, exposed in a 365 nm ultraviolet light source, and developed in a PGMEA developer. The obtained pattern was shown in FIG. 9.

### Example 4

The same experimental method as Example 3 was used. The following photosensitive ligands were used instead of 2-(6-(2-(methacryloxy)ethoxy)-2-oxo-2H-chromen-3-yl)acetic acid to achieve the same technical effect.

(2E)-3-(3-methoxy-4-{2-[(2-methylprop-2-enoyl)oxy]ethoxy}phenyl)prop-2-enoic acid.

4-(4-(methacryloxy)phenoxy)-4-oxobutyric acid.

Mono-2-(methacryloxy)ethyl succinate.

(E)-6-(4-(methacryloxy)phenyl)-4-oxyhex-5-enoic acid.

(E)-6-(4-(methacryloxy)-3-methoxyphenyl)-4-oxohex-5-enoic acid.

(E)-6-(4-(methacryloxy)-3,5-dimethoxyphenyl)-4-oxohex-5-enoic acid.

Phenyl-[4-(10-mercaptodecyloxy)phenyl]ketone, phenyl-[4-(10-mercaptodecylthio)phenyl]ketone.

4-pyrrolidinyl-phenyl-[4-(10-mercaptodecylthio)phenyl]ketone.

### Example 5

The same experimental method as Example 3 was used. CdS, CdSe, CdSe/ZnS, CdSeS/ZnS, CdSe/CdZnSeS/ZnS, CdZnS/ZnS, CdZnSe/ZnS, ZnSe/ZnS, CdSe/CdS, CdSeS/CdS, InP, InP/ZnS, InP/ZnSe/ZnS, InGaP/ZnSe/ZnS, CdTe, PbS, PbSe, PbS/CdS, Fe₂O₃, Fe₃O₄, TiO₂, ITO, In₂O₃, CsPbBr₃, and MAPbBr₃ nanocrystals were used instead of CdSe/CdZnSeS quantum dots to achieve the same technical effect.

### Example 6

The same experimental method as Example 3 was used. Octane, ethylene glycol methyl ether acetate (EGMEA), diethylene glycol mono-ether acetate (DGMEA), or propylene glycol methyl ether (PGME) was used instead of propylene glycol methyl ether acetate (PGMEA) to achieve the same technical effect.

It should be noted that the above examples are only preferred embodiments of the present invention and are not used to limit the scope of protection of the present invention. Equivalent replacements or substitutions made on the basis of the above all fall within the scope of protection of the present invention.

What is claimed is:

1. A green photosensitive nanocrystal coating, comprising nanocrystals and a photosensitive ligand, wherein the photosensitive ligand contains a functional group that coordinates with the nanocrystals, and a methacryloyl or benzophenone photosensitive group, wherein the photosensitive ligand is one of ethyl 2-(3-mercaptopropionyloxy) methacrylate, 5-[3-methoxy-4-(2-methylprop-2-enoyloxy)phenyl]pent-4-enoic acid, (2E)-3-(3-methoxy-4-{2-[(2-methylprop-2-enoyl)oxy]ethoxy}phenyl)prop-2-enoic acid, 4-(4-(methacryloxy)phenoxy)-4-oxobutyric acid, mono-2-(methacryloxy)ethyl succinate, (E)-6-(4-(methacryloxy)phenyl)-4-oxyhex-5-enoic acid, (E)-6-(4-(methacryloxy)-3-methoxyphenyl)-4-oxohex-5-enoic acid, (E)-6-(4-(methacryloxy)-3,5-dimethoxyphenyl)-4-oxohex-5-enoic acid, 2-(6-(2-(methacryloxy)ethoxy)-2-oxo-2H-chromen-3-yl)acetic acid, phenyl-[4-(10-mercaptodecyloxy)phenyl]ketone, phenyl-[4-(10-mercaptodecylthio)phenyl]ketone, and 4-pyrrolidinyl-phenyl-[4-(10-mercaptodecylthio)phenyl]ketone.

2. The green photosensitive nanocrystal coating according to claim 1, wherein the functional group coordinated with the nanocrystals is any one or several of carboxylate, amino, and mercapto groups.

3. (canceled)

4. The green photosensitive nanocrystal coating according to claim 1, wherein the nanocrystals are any one of CdS, CdSe, CdSe/ZnS, CdSeS/ZnS, CdSe/CdZnSeS, CdSe/CdZnSeS/ZnS, CdZnS/ZnS, CdZnSe/ZnS, ZnSe/ZnS, CdSe/CdS, CdSeS/CdS, InP, InP/ZnS, InP/ZnSe/ZnS, InGaP/ZnSe/ZnS, CdTe, PbS, PbSe, PbS/CdS, Fe₂O₃, Fe₃O₄, TiO₂, ITO, In₂O₃, CsPbBr₃, and MAPbBr₃; the nanocrystals contain a primitive organic ligand, and the primitive organic ligand is any one or a combination of carboxylic acid, phosphonic acid, and amine with fatty chains greater than 8 carbons.

5. A preparation method for the green photosensitive nanocrystal coating according to claim 1, comprising the following steps: adding the photosensitive ligand to a nanocrystal solution with an organic ligand on a surface to obtain a mixture, and vigorously stirring or shaking the mixture to obtain a precipitate, namely, a product.

6. The preparation method according to claim 5, wherein a 25 mg/mL nanocrystal solution with the organic ligand on the surface is mixed with the photosensitive ligand in a volume ratio of 10:1, and an obtained mixture is vigorously stirred or shaken until the precipitate, namely, the product is generated.

7. A preparation method for a green photosensitive nanocrystal ink, wherein the green photosensitive nanocrystal coating according to claim 1 is dispersed in a green solvent, and the green solvent is propylene glycol methyl ether acetate, ethylene glycol methyl ether acetate, octane, diethylene glycol mono-ether acetate, or propylene glycol methyl ether.

8. The preparation method according to claim 7, wherein the green photosensitive nanocrystal coating is dispersed in the green solvent to form a stable colloidal solution, and a concentration of the green photosensitive nanocrystal coating is 10-25 mg/mL.

9. A photoresist-free optical patterning method for colloidal nanocrystals in a green solvent, comprising the following steps: using the green photosensitive nanocrystal ink according to claim 7 to prepare a continuous, dense, and thickness-controllable nanocrystal thin film on a substrate; pressing a mask engraved with a specific pattern onto the continuous, dense, and thickness-controllable nanocrystal thin film, exposing in an ultraviolet light source, and developing in a developer.

10. The method according to claim 9, wherein the substrate is a silicon wafer, a quartz plate, or a glass sheet; and the developer is propylene glycol methyl ether acetate, ethylene glycol methyl ether acetate, octane, diethylene glycol mono-ether acetate, or propylene glycol methyl ether.

11. The preparation method according to claim 5, wherein in the green photosensitive nanocrystal coating, the functional group coordinated with the nanocrystals is any one or several of carboxylate, amino, and mercapto groups.

12. The preparation method according to claim 5, wherein in the green photosensitive nanocrystal coating, the nanocrystals are any one of CdS, CdSe, CdSe/ZnS, CdSeS/ZnS, CdSe/CdZnSeS, CdSe/CdZnSeS/ZnS, CdZnS/ZnS, CdZnSe/ZnS, ZnSe/ZnS, CdSe/CdS, CdSeS/CdS, InP, InP/ZnS, InP/ZnSe/ZnS, InGaP/ZnSe/ZnS, CdTe, PbS, PbSe, PbS/CdS, Fe₂O₃, Fe₃O₄, TiO₂, ITO, In₂O₃, CsPbBr₃, and MAPbBr₃; the nanocrystals contain a primitive organic ligand, and the primitive organic ligand is any one or a combination of carboxylic acid, phosphonic acid, and amine with fatty chains greater than 8 carbons.

13. The preparation method according to claim 7, wherein in the green photosensitive nanocrystal coating, the functional group coordinated with the nanocrystals is any one or several of carboxylate, amino, and mercapto groups.

14. The preparation method according to claim 7, wherein in the green photosensitive nanocrystal coating, the nanocrystals are any one of CdS, CdSe, CdSe/ZnS, CdSeS/ZnS, CdSe/CdZnSeS, CdSe/CdZnSeS/ZnS, CdZnS/ZnS, CdZnSe/ZnS, ZnSe/ZnS, CdSe/CdS, CdSeS/CdS, InP, InP/ZnS, InP/ZnSe/ZnS, InGaP/ZnSe/ZnS, CdTe, PbS, PbSe, PbS/CdS, Fe₂O₃, Fe₃O₄, TiO₂, ITO, In₂O₃, CsPbBr₃, and MAPbBr₃; the nanocrystals contain a primitive organic ligand, and the primitive organic ligand is any one or a combination of carboxylic acid, phosphonic acid, and amine with fatty chains greater than 8 carbons.
